(19) United States
(12) Patent Application Publication
(10) Pub. No.: US 2016/0036450 A1
(43) Pub. Date: Feb. 4, 2016

(54) METHOD OF OPTIMIZING DISPATCH OF VARIABLE SPEED ENGINE-GENERATOR SETS

(71) Applicant: Innovus Power, Inc., Freemont, CA (US)

(72) Inventors: John MCCALL, Freemont, CA (US); Brendan TAYLOR, Freemont, CA (US)

(73) Assignee: Innovus Power, Inc., Freemont, CA (US)

(21) Appl. No.: 14/812,736

(22) Filed: Jul. 29, 2015

Related U.S. Application Data
(60) Provisional application No. 62/030,365, filed on Jul. 29, 2014.

(51) Int. Cl. H03L 5/02; G05B 13/02

(52) U.S. Cl. CPC H03L 5/02; G05B 13/021

(57) ABSTRACT

A method of optimizing the dispatch of generators connected to an electrical grid. At least one of the gensets is a variable-speed genset. The optimum dispatch for each load condition is continuously updated by changing the load distribution slightly, testing for performance improvement and updating the distribution set points if improvement is found. Alternatively, the power system may be controlled so that the optimum dispatch for each load condition is determined with the use of an online model that is continuously updated with actual operational data to thereby determine the optimum dispatch.

### CROSS-REFERENCE TO RELATED APPLICATIONS

The present application claims priority to and the benefit of U.S. Provisional Patent Application No. 62/030,365, filed Jul. 29, 2014. The foregoing provisional application is incorporated by reference herein in its entirety.

### BACKGROUND

Electrical networks that are isolated from the larger electrical “grid”, may be referred to as microgrids. In these microgrids, it is common to have multiple engine-generator sets (usually diesel engines), or gensets providing power to the microgrid. See, for example, U.S. Published Patent Application No. 2014-0097683 (incorporated by reference herein). The gensets can run independently, or in parallel. The process of determining which genset(s) to run at any given time, and how to share load among them when running in parallel, is commonly called “dispatching.” In a microgrid, it is often the case that a genset must be run at relatively low load in order to be prepared to provide enough generation capacity to handle a large, sudden increase in load. This extra capacity is called spinning reserve. If renewable energy sources are included in the microgrid, even more spinning reserve may be required to account for the additional variability of the “net load” (actual load minus renewable power contribution).

A fixed-speed genset (FSG) is less efficient when running significantly below rated power, and this can also lead to maintenance and emissions issues due to lower-temperature combustion at lower load. The need for spinning reserve can lead to lower fuel efficiency and increased maintenance in microgrids that are powered by only fixed-speed gensets.

A variable speed genset (VSG) can run at relatively low loads with much better efficiency and emissions, and lower maintenance costs, than a FSG. Furthermore, it is sometimes the case that the total system fuel efficiency, which is the combined fuel efficiency of all operating gensets in a microgrid, can be improved by shifting load away from the VSG(s) toward the FSG(s), which might not yield the best fuel efficiency result for the VSG when considering it alone. Thus, there is a need to find the optimum dispatch that maximizes system fuel efficiency when a VSG is included in a microgrid.

Microgrids may be used to provide power to components in remote locations that do not have access to the conventional grid. For example, in many oil production sites, there is no electric grid available to supply power. In this situation, it is common to use a FSG to supply power for a pump used in oil production. In some cases an inverter (i.e., a variable frequency drive (VFD)) is used between the genset and the pump to provide a range of pump speed, and/or to reduce large in-rush currents when the pump starts. However, when the pump load is significantly below rated output of the FSG, the fuel efficiency is reduced, emissions are worse and maintenance is increased due to reduced combustion quality.

### SUMMARY

A method of controlling the sharing load between a plurality of electrical generators connected to an electrical grid supplying power to an electrical load is disclosed herein. At least one of the generators is a variable speed generator driven by an engine. Each of the generators dispatch and provide power based on a distribution set point that varies based on the load on the electrical grid. The method includes changing the load distribution between the plurality of generators and monitoring the efficiency of the generators to determine whether the efficiency of the generators is improved after the changing of the load distribution. If the efficiency of the generators is improved, the distribution set point is changed to reflect the current load distribution.

A method of controlling the sharing load between a plurality of electrical generators connected to an electrical grid supplying power to an electrical load is disclosed herein. At least one of the generators is a variable speed generator driven by an engine. Each of the generators dispatch and provide power based on a distribution set point that varies based on the load on the electrical grid. The method includes continuously monitoring data related to the operation of the generators. The data being monitored includes at least one of the following: current price of fuel being supplied to the engine; costs for maintaining at least one of the generators; history of load applied to the electrical grid; actual load on the electrical grid; time that the engine has been running The method also includes changing the distribution set point based on the monitoring of the data to thereby change the distribution of load between plurality of generators.

### BRIEF DESCRIPTION OF THE DRAWINGS

Features, aspects and advantages of the present invention will become apparent from the following description and the accompanying exemplary embodiments shown in the drawings, which are briefly described below.

FIG. 1 is a block diagram of an exemplary power supply system for a pump.

FIG. 2 is a block diagram of an exemplary power supply system for a pump.

### DETAILED DESCRIPTION

This application discloses a system and method for employing the combination of a variable speed engine-generator set and an electric pump connected through a full power converter that allows the engine to run at its optimum speed for the given load conditions, and allows the pump to run at an independent speed. This application discloses two methods for optimizing total system fuel efficiency of a system of engine-generator sets (gensets) that includes at least one variable speed genset, which can be operated independently or in parallel with the ability to share load in any proportion.

The first method of optimizing total system fuel efficiency uses a technique known as “perturb and observe,” where, for a particular load condition, the load distribution among the gensets is changed slightly from the currently stored set point in a particular direction within the search space (perturb). The perturb step may include varying the load distribution in the range of 0.5 to 5 percent in order to determine assess performance Then, the system is observed to see if there is improvement in performance. If “yes” (i.e., performance improves), the currently stored set point is updated with the new value. The process is repeated until the maximum performance is found for the given load condition, and for a finite number of steps in load condition. In this way the system is always optimized even if performance conditions within the system change (e.g. an engine is rebuilt).

The first method may be more applicable to a s system utilizing a smaller number of gensets (e.g., two or three). The first method, which can be referred to as a Perturb and Observe system, starts with an estimated dispatch algorithm calculated from load data collected prior to installation of this system. In addition to fuel efficiency, there are many other factors that could be considered when determining which gensets to operate. For example, the following factors could be considered: the expected and/or actual load at this time; the expected and/or actual variability of the load at this time; the largest step load in the system; if a renewable power source in the system, the output and variability of the renewable power source. After determining which gensets need to be operated to meet the load requirements, the optimum load sharing must still be determined.

The perturb and observe method may be described with reference to the following example. For example, a system is provided with two gensets. The first genset is a 1000-kW fixed-speed genset (G1), and the second genset is a 750-kW variable speed genset (G2). An exemplary load condition exists on the system. For example, the present load condition is 1200 kW on average with a small amount of variability. The range of possible load distributions among the two gensets, is bounded by the maximum output of each genset:
G1=1000 kW, G2=200 kW
G1=450 kW, G2=750 kW

If the present distribution for this load is set at G1=900 kW and G2=300 kW, then the system may be “perturbed” so that the new load condition might be G1=925 kW and G2=275 kW. The system is observed and, if it is found that this load sharing condition improves the overall system efficiency, then this load distribution becomes the new distribution set point for 1200 kW load. This two genset example is essentially a one-dimensional search space.

If the system has three gensets, it becomes a two-dimensional search space. For a given load, the perturb and observe “test” would include, for example, the following conditions:
1) altering the distribution of load between G1 and G2 while holding G3 steady, and
2) altering the distribution of load between G1 and G3 while holding G2 steady.

In this way, the control system finds the local gradient of the search space, and moves in the “most uphill” (i.e., adjusts the load in a way to cause the largest relative perturbation) direction with each test iteration until the local maximum is found. The method determines a load distribution based on a local maximum efficiency which may not correspond to a global maximum efficiency.

The second method of optimizing total system fuel efficiency uses an online model, which includes a more complete set of considerations, such as fuel price, actual maintenance costs and historical load data, to determine the optimum dispatch of gensets. The online model is continuously updated with real operating data so that its solution reflects changes in the system for which it is used. The second method utilizes a mode that is available to the control system in real time and can be used to make control decisions, that is designed to “learn” from real-time operating data, includes a more complete economic model, and may be more appropriate for complex systems that include three or more gensets.

The second method, may be referred to as the Online Learning Model (OLM) method, is used to solve the same dispatch problem for a system of three or more gensets. The OLM includes the use of an online model (i.e. one that is available to the control system in real-time, allowing it to make control decisions based on modeling results). The system is modeled more completely, including economic factors such as price of fuel and maintenance costs, and is constantly updated with real data from the system (e.g. load data, engine run hours, etc.), thereby “learning” about the actual system and adjusting its dispatch result accordingly. Since this is computationally intensive, the model is run on a separate computer from the control system or, alternatively, even on a different network, but to which the control system has access.

This application also discloses an improved power system. The power system supplied by a plurality of gensets, at least one of the gensets is a variable-speed genset, in which the optimum dispatch for each load condition is continuously updated by changing the load distribution slightly, testing for performance improvement and updating the distribution set points if improvement is found. Alternatively, the power system may be controlled so that the optimum dispatch for each load condition is determined with the use of an online model that is continuously updated with actual operational data to improve the accuracy of the model and thereby the optimum dispatch.

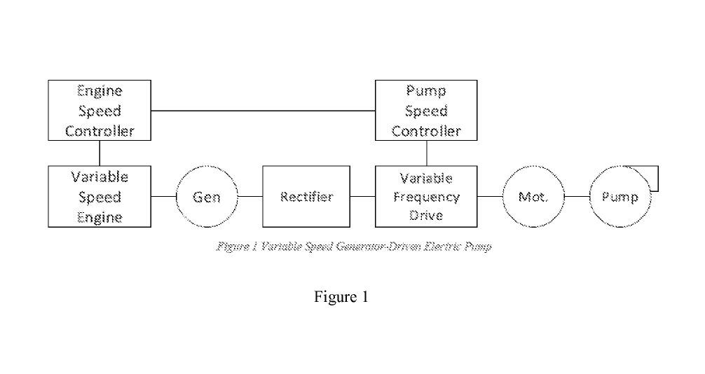

A system for determining the optimum speed for operating the engine of the variable speed generator set is also disclosed. For example, for a system including a single genset (such as shown in FIG. 1), the engine may run at its optimum speed for the given load because the active rectifier converts the variable frequency/variable voltage AC from the generator to DC. The VFD converts the DC power into AC at the frequency required to drive the pump at the desired speed. In this configuration, the Engine Speed Controller (ESC) determines the optimum speed for the engine using the method described in U.S. Provisional Patent Application Ser. No. 62/007,736, titled A Method For Tracking the Maximum Efficiency Point of a Variable Speed Engine-Generator Set (incorporated by reference herein). According to this method, the ESC is loaded with an initial set of operating points, or a “load-speed curve”, which consist of a speed set point for a corresponding power output. As the system operates and encounters a particular load condition, it uses a “perturb and observe” method to try a new speed set point, see if it improves the fuel efficiency of the engine, and if yes, updates the load-speed curve. For example, at a load of 500 kW the current speed set point is 1400 RPM, according to the load-speed curve. The next time an average load of 500 kW is encountered for a sustained period of e.g. one minute, the speed set point is reduced to 1375 RPM. If the fuel efficiency is seen to improve at this new speed, the load-speed curve is updated to use 1375 RPM instead of 1400 RPM. If the fuel efficiency worsens, the next time a 500 kW load is encountered, the ESC will try 1425 RPM. If this is found to improve efficiency, then 1400 RPM is replaced with 1425 RPM in the load-speed curve; if not, then 1400 RPM remains as the speed set point for 500 kW load.

Since the engine's efficiency can change over time as components degrade, or are replaced, and possibly from unit to unit, this search algorithm may be continuously applied throughout the life of the system, thus ensuring that the engine is always running at its optimum efficiency. In the system described in FIG. 1, the Pump Speed Controller (PSC) sets the Variable Frequency Drive (VFD) speed for the application requirements. It is important to note that the VFD shown in FIG. 1 may include line filters that improve the quality of the power delivered to the pump motor by reducing harmonic content.

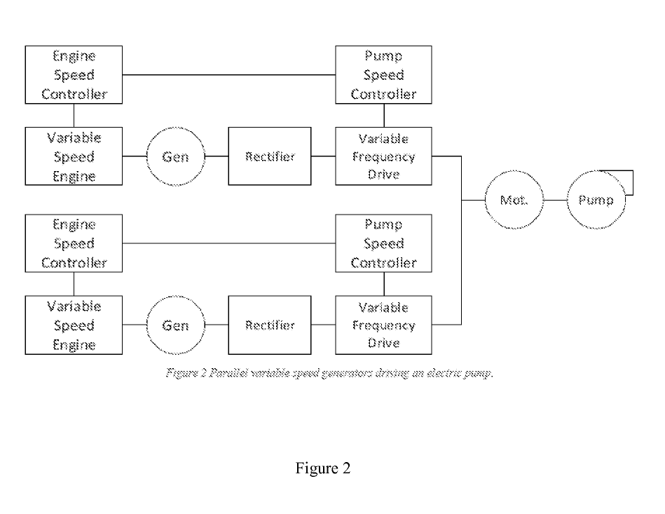

In an alternative embodiment, shown in FIG. 2, The system includes two variable speed generators operating in parallel, driving the pump. In some applications it is desirable to have redundancy so that if one power source fails the other can carry the load, or at least part of the load, until it is repaired or replaced. Although a pump is disclosed as one example of a load on a microgrid system, the system disclosed herein may be used to power any microgrid regardless of the loads being supplied by the microgrid. The disclosure of a pump is exemplary only.

Thus, a system is disclosed that includes a variable speed engine-generator set electrically connected to a full power converter, with the inverter side of the converter electrically connected to an electric motor that is mechanically connected to a pump, whereby the speed of the electric pump is set by the output frequency of the inverter, and is optimized to the pumping application, and the speed of the engine is independently optimized to maximize fuel efficiency. The system may include an additional variable speed engine-generator set and full power converter connected in parallel, both supplying power to a single electric motor and pump.

For purposes of this disclosure, the term “coupled” means the joining of two components (electrical or mechanical) directly or indirectly to one another. Such joining may be stationary in nature or movable in nature. Such joining may be achieved with the two components (electrical or mechanical) and any additional intermediate members being integrally formed as a single unitary body with one another or with the two components or the two components and any additional member being attached to one another. Such joining may be permanent in nature or alternatively may be removable or releasable in nature.

It is important to note that the construction and arrangement of the systems and methods disclosed herein are illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter disclosure herein. For example, elements shown as integrally formed may be constructed of multiple parts or elements, the position of elements may be reversed or otherwise varied, and the nature or number of discrete elements or positions may be altered or varied. Accordingly, all such modifications are intended to be included within the scope of the present application. The order or sequence of any process or method steps may be varied or re-sequenced according to alternative embodiments. Other substitutions, modifications, changes and omissions may be made in the design, operating conditions and arrangement of the exemplary embodiments.

What is claimed is:

1. A method of controlling the sharing load between a plurality of electrical generators connected to an electrical grid supplying power to an electrical load, wherein at least one of the generators is a variable speed generator driven by an engine, and wherein each of the generators dispatch and provide power based on a distribution set point that varies based on the load on the electrical grid, the method comprising the steps of:
(a) changing the load distribution between the plurality of generators;
(b) monitoring the efficiency of the generators to determine whether the efficiency of the generators is improved after the changing of the load distribution;
(c) if the efficiency of the generators is improved, changing the distribution set point to reflect the current load distribution;
(d) repeating steps (a)-(c).

2. The method of claim 1, further comprising the step of collecting load data for at least one of the generator sets and preparing a dispatch algorithm to determine the distribution set point prior to connecting at least one of the generators to the electrical grid.

3. The method of claim 1, wherein the plurality of generators includes at least three generators and wherein during step (a) the load distribution is changed so that the load on at least one of the three generators remains unchanged.

4. The method of claim 1, wherein during step (a) the amount that the load distribution is changed is limited by a maximum electrical power output of each of the plurality of generators.

5. The method of claim 1, wherein at least one of the generators is a fixed speed generator.

6. The method of claim 1, further comprising the step of determining which of the plurality of generators to operate, and wherein steps (a)-(d) are performed after the step of determining.

7. The method of claim 6, wherein the step of determining is based on at least one of the following factors: expected load on the electrical grid; actual load on the electrical grid, expected variability of the load on the electrical grid; actual variability of the load on the electrical grid; the size of the largest load connected to the electrical grid; and the presence and capability of a renewable power source connected to the electrical grid.

8. A method of controlling the sharing load between a plurality of electrical generators connected to an electrical grid supplying power to an electrical load, wherein at least one of the generators is a variable speed generator driven by an engine, and wherein each of the generators dispatch and provide power based on a distribution setpoint that varies based on the load on the electrical grid, the method comprising the steps of:
(a) continuously monitoring data related to the operation of the generators, wherein the data being monitored includes at least one of the following: current price of fuel being supplied to the engine; costs for maintaining at least one of the generators; history of load applied to the electrical grid; actual load on the electrical grid; time that the engine has been running; and
(b) changing the distribution setpoint based on the monitoring of the data to thereby change the distribution of load between plurality of generators.

9. The method of claim 8, further comprising the step of determining which of the plurality of generators to operate, and wherein steps (a)-(b) are performed after the step of determining.

10. The method of claim 9, wherein the step of determining is based on at least one of the following factors: expected load on the electrical grid; actual load on the electrical grid, expected variability of the load on the electrical grid; actual variability of the load on the electrical grid; the size of the largest load connected to the electrical grid; and the presence and capability of a renewable power source connected to the electrical grid.
